(19) United States
(12) Patent Application Publication
(10) Pub. No.: US 2025/0040305 A1
(43) Pub. Date: Jan. 30, 2025

(54) METHOD FOR MANUFACTURING SEPARABLE SEMICONDUCTOR SUBSTRATE, AND SEMICONDUCTOR SUBSTRATE, THIN FILM DEVICE AND COMPOSITE DEVICE MANUFACTURED BY THE SAME

(71) Applicant: LumiGNtech Co., Ltd., Gyeonggi-do (KR)

(72) Inventors: Hae Yong LEE, Gwangmyeong-si (KR); Young Jun CHOI, Seoul (KR); Hae Gon OH, Gwangmyeong-si (KR)

(73) Assignee: LumiGNtech Co., Ltd., Gyeonggi-do (KR)

(21) Appl. No.: 18/781,658

(22) Filed: Jul. 23, 2024

(30) Foreign Application Priority Data
Jul. 24, 2023 (KR) 10-2023-0096285
Jul. 1, 2024 (KR) 10-2024-0086323

(51) Int. Cl. H01L 33/32; H01L 33/00

(52) U.S. Cl. CPC H01L 33/32; H01L 33/007; H01L 33/0093

(57) ABSTRACT

The present invention relates to a method of manufacturing a separable semiconductor substrate, and a thin film device and composite device manufactured by the same, and the method of manufacturing a separable semiconductor substrate according to an embodiment of the present invention includes providing a substrate and forming a buffer layer including carbon and aluminum nitride.

### CROSS-REFERENCE TO RELATED APPLICATION

This application claims priority to and the benefit of Korean Patent Application No. 10-2023-0096285, filed on Jul. 24, 2023, and Korean Patent Application No. 10-2024-0086323, filed on Jul. 1, 2024, the disclosures of which are incorporated herein by reference in their entirety.

### BACKGROUND

### 1. Technical Field

The present invention relates to a method of manufacturing a separable semiconductor substrate, and a thin film device and composite device manufactured by the same, and more particularly, to a method of manufacturing a separable semiconductor substrate for growing and separating compound semiconductor crystals, and a thin film device and composite device manufactured by the same.

### 2. Discussion of Related Art

Compound semiconductors are generally referred to as semiconductors including two or more types of elements, and the use of the compound semiconductors is becoming essential to improve the performance of semiconductor devices and solve heat generation problems.

Among various compound semiconductors, key materials expected rapid growth include gallium nitride (GaN), aluminum nitride (AlN), aluminum gallium nitride (AlGaN), silicon carbide (SiC), and gallium oxide (Ga₂O₃).

Gallium nitride (GaN), aluminum nitride (AlN), aluminum gallium nitride (AlGaN), and the like are III-V compound semiconductors, and are being applied and researched as materials for wafers that improve the power efficiency of optoelectronic devices, emitters, detectors, and advanced high-performance semiconductors operating with full-bandwidth wavelengths.

The above-described compound semiconductors are generally manufactured by growing an epitaxial layer on a sapphire (Al₂O₃), silicon (Si), or silicon carbide (SIC) substrate and then separating the substrate.

Among separation methods, there is a self-separation method, and a separation method by inserting a pattern and a buffer layer are reported as the self-separation method.

The separation method by inserting the pattern uses a photolithography process of a typical semiconductor process, which has a disadvantage of being expensive and complicated.

The separation method by inserting a buffer layer uses stress induced by a difference in thermal expansion coefficient during cooling, and has a problem of poor separation or a problem in that it is difficult to manufacture large-area substrates due to reduced crystallinity.

Therefore, development of a technology that is inexpensive and capable of manufacturing large-area substrates is required.

Meanwhile, the above-described background technology cannot necessarily be said to be known technology disclosed to the general public before the application for the present invention.

### RELATED ART DOCUMENT

### Patent Document

Japanese Patent Registration No. 5307975 B2, “Nitride semiconductor substrate and its manufacturing method and epitaxial substrate for nitride semiconductor light-emitting device” (registered on Jul. 5, 2013)

### SUMMARY OF THE INVENTION

The present invention is directed to providing a method of manufacturing a separable semiconductor substrate that is inexpensive and capable of manufacturing a large-area compound semiconductor substrate, and a separable semiconductor substrate manufactured by the same.

The present invention is also directed to providing a thin film device and a composite device that are manufactured by a method of manufacturing a separable semiconductor substrate.

According to an aspect of the present invention, there is provided a method of manufacturing a separable semiconductor substrate, which includes providing a substrate and forming a buffer layer including carbon and aluminum nitride.

The method may further include forming a compound semiconductor layer on the buffer layer and guiding the compound semiconductor layer to be self-separated.

The compound semiconductor layer may include gallium nitride (GaN), aluminum nitride (AlN), and aluminum gallium nitride (AlGaN).

The substrate may be a sapphire substrate with a size of 2 inches or more.

The forming of the buffer layer may include performing carbonization for forming the carbon, performing nitridation on an upper surface of the carbon, and forming the aluminum nitride on the nitrided upper surface of the carbon.

According to another aspect of the present invention, there is provided a separable semiconductor substrate which includes a mother substrate, and a buffer layer disposed on the mother substrate and including carbon and aluminum nitride.

The separable semiconductor substrate may have a size of 2 inches or more.

An average light transmittance of the separable semiconductor substrate may have an average light transmittance reduced by 20 to 80% compared to an average light transmittance of the mother substrate with respect to light having a wavelength of 400 nm.

The buffer layer may include a carbon layer, a nitridated carbon layer, and an aluminum nitride layer.

The carbon layer may have a three-dimensional structure.

The carbon layer may be an amorphous layer that has an sp3 structure with a peak around a wavelength of 1,620 cm⁻¹ in a D band in a Raman spectrum.

The carbon layer may have a surface roughness Ra of 27 nm or less and a surface roughness Rt of 310 nm or less.

The aluminum nitride layer may have a surface roughness Ra of 20 nm or less and a surface roughness Rt of 170 nm or less.

The separable semiconductor substrate may further include a first electronic device disposed on the buffer layer.

The mother substrate may be separable from the buffer layer.

The separable substrate may further include a stress layer that covers the first electronic device and a support layer disposed on the stress layer.

The separable semiconductor device may further include a second electronic device including a second device layer in contact with a surface of a first device layer of the first electronic device and formed as a single structure with the first device layer.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a flowchart of a method of manufacturing a separable semiconductor substrate according to an embodiment of the present invention;

FIG. 2 is a graph showing a change in temperature in an operation of forming a buffer layer in a method of manufacturing a separable semiconductor substrate according to an embodiment of the present invention;

FIG. 3 is a graph showing a change in flow rate of inflow gas in an operation of forming a buffer layer in a method of manufacturing a separable semiconductor substrate according to an embodiment of the present invention;

FIGS. 4A to 4B are sets of cross-sectional views for describing a method of manufacturing a separable semiconductor substrate according to an embodiment of the present invention;

FIGS. 5A to 5D are sets of cross-sectional views for describing a method of manufacturing a separable semiconductor substrate according to an embodiment of the present invention and a method of manufacturing a compound semiconductor substrate using the same;

FIG. 6 is a cross-sectional view for describing a thin film device according to an embodiment of the present invention;

FIG. 7 is a flowchart of a method of manufacturing a thin film device according to an embodiment of the present invention;

FIGS. 8A to 8F are sets of cross-sectional views for describing the method of manufacturing a thin film device of FIG. 7;

FIG. 9 is a cross-sectional view for describing a composite device according to an embodiment of the present invention;

FIG. 10 is a flowchart of a method of manufacturing a composite device according to an embodiment of the present invention;

FIGS. 11A to 11F are schematic diagrams for describing the method of manufacturing a composite device of FIG. 10;

FIG. 12 is a graph of transmittances of semiconductor substrates that are obtained using ultraviolet-visible (UV-Vis) spectrophotometry according to a thickness of a carbon-containing layer of a separable semiconductor substrate according to an embodiment of the present invention;

FIG. 13 is a Raman spectrum for a separable semiconductor substrate according to an embodiment of the present invention;

FIG. 14 is a photograph of a surface shape according to a thickness of a carbon-containing layer of a separable semiconductor substrate according to an embodiment of the present invention.

FIG. 15 is a photograph of a surface shape of an aluminum nitride layer of a separable semiconductor substrate according to an embodiment of the present invention; and

FIG. 16 is a photograph of an aluminum nitride layer that is separated from a sapphire substrate after the aluminum nitride layer is grown on a separable semiconductor substrate according to an embodiment of the present invention.

FIG. 17 is a photograph of a gallium nitride layer that is separated from a sapphire substrate after the gallium nitride layer is grown on a separable semiconductor substrate according to an embodiment of the present invention.

### DETAILED DESCRIPTION OF EXEMPLARY EMBODIMENTS

Hereinafter, embodiments of the present invention that are easily performed by those skilled in the art will be described in detail with reference to the accompanying drawings. However, the embodiments of the present invention may be implemented in several different forms and are not limited to embodiments described herein. In addition, parts irrelevant to description are omitted in the drawings in order to clearly explain the present invention. Similar parts are denoted by similar reference numerals throughout this specification.

Throughout this specification, when a part is referred to as being “connected” to another part, it includes “directly connected” and “indirectly connected” via an intervening part. In addition, when a certain part “includes” a certain component, this does not exclude other components from being included unless described otherwise, and other components may in fact be included.

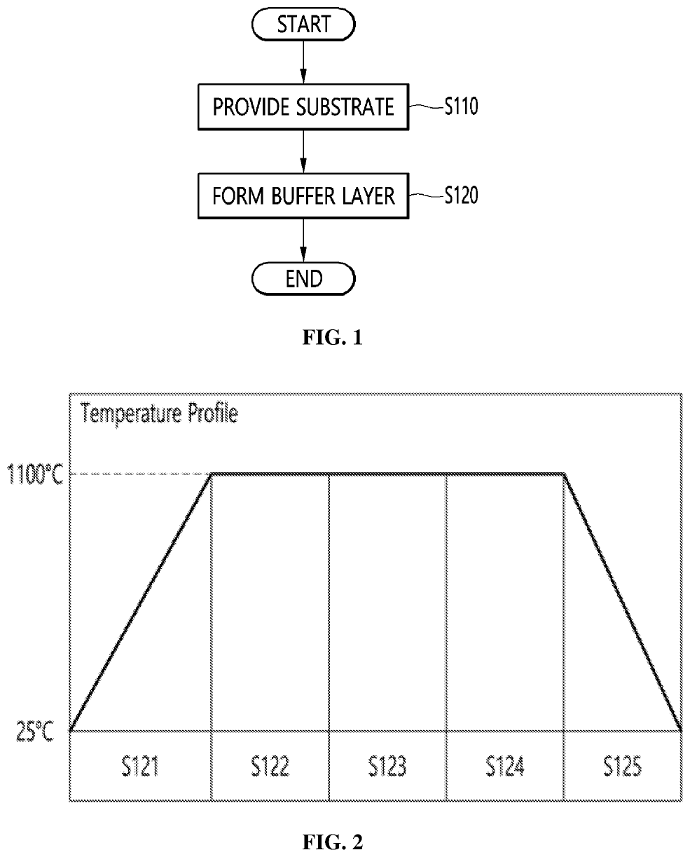

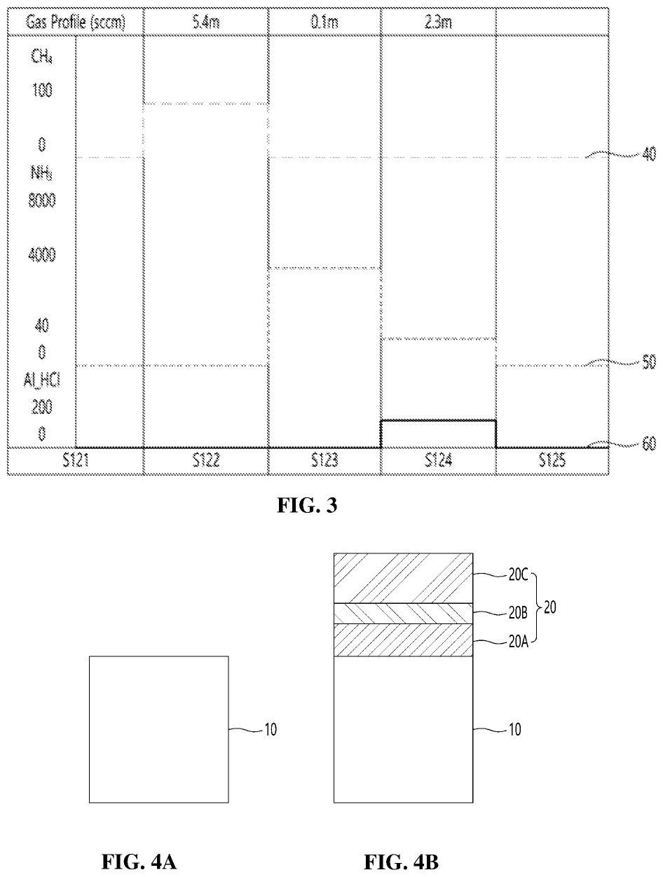

FIG. 1 is a flowchart of a method of manufacturing a separable semiconductor substrate according to an embodiment of the present invention. FIG. 2 is a graph showing a change in temperature in an operation of forming a buffer layer in the method of manufacturing a separable semiconductor substrate according to the embodiment of the present invention. FIG. 3 is a graph showing a change in flow rate of inflow gas in the operation of forming a buffer layer in the method of manufacturing a separable semiconductor substrate according to the embodiment of the present invention. FIGS. 4A and 4B are sets of cross-sectional views for describing a method of manufacturing a separable semiconductor substrate according to an embodiment of the present invention.

The present invention will be described with reference to FIGS. 1 to 4B.

The method of manufacturing a separable semiconductor substrate includes an operation S110 of providing a substrate, and an operation S120 of forming a buffer layer including carbon and aluminum nitride.

The operation S110 of providing a substrate is an operation of providing a mother material for growing a separable semiconductor substrate. A sapphire substrate with a size of 2 inches or more may be provided, but the present invention is not limited thereto. For example, a Si or SiC substrate may be provided. Accordingly, a large-area compound semiconductor layer to be manufactured can be formed.

The operation S120 of forming a buffer layer is an operation of forming a separation guide layer so that a compound semiconductor can be grown with excellent crystallinity and the compound semiconductor layer can be easily separated from a substrate later, and the operation S120 of forming a buffer layer may be performed at a temperature of 1,000° C. or higher, preferably, at a temperature of 1,000° C. or higher and 1,600° C. or lower, more preferably, at a temperature of 1,000° C. or higher and 1,200° C. or lower, and furthermore preferably, at a temperature of 1,100° C.

When the operation S120 is performed at a temperature less than 1,000° C., a diffusion rate of carbon for homogeneous nucleation and growth can be reduced.

The operation S120 of forming a buffer layer includes an operation of performing carbonization for forming the carbon, an operation of performing nitridation on an upper surface of the carbon, and an operation of forming aluminum nitride on the nitrided upper surface of the carbon.

The operation of performing carbonization and the operation of performing nitridation may be operations of performing an in-situ method using a hydride vapor-phase epitaxy (HVPE) device, and preferably, a horizontal HVPE device, but the present invention is not limited thereto. For example, a metalorganic chemical vapor deposition (MOCVD) device, a sputtering device, a plasma-enhanced chemical vapor deposition (PECVD) device, or an atomic layer deposition (ALD) device may be used.

For example, among a plurality of growth devices, a horizontal HVPE device may have a structure in which six independently controlled heaters are disposed.

The horizontal HVPE device may have a source zone and a growth zone in a quartz reactor.

Methane (CH₄), ammonia (NH₃), hydrogen chloride (HCl), and nitrogen (N₂) gas supply lines may be provided at one end of the source zone. A unit of flow rate of gas supplied to each line is standard cubic centimeters per minute (sccm).

Meanwhile, referring to FIGS. 2 and 3, the operation of performing carbonization and the operation of performing nitridation include, in detail, an operation S121 of loading a substrate, an operation S122 of performing carbonization, and an operation S123 of performing nitridation.

The operation S121 of loading a substrate is an operation of loading a substrate in the growth zone. In this case, as illustrated in FIG. 2, a temperature is increased from 25° C. to 1,100° C. and then maintained at 1,100° C.

The operation S122 of performing carbonization is an operation of forming carbon on the substrate. Here, CH₄ gas may be supplied at a flow rate of 500 sccm or less within 20 minutes, and preferably, at a flow rate of 10 sccm or more and 300 sccm or less for 2 minutes or more and 20 minutes or less.

In this case, as illustrated in FIG. 2, the temperature may be maintained at 1,100° C., and as illustrated in FIG. 3, CH₄ gas may be introduced at a flow rate of 100 sccm. The operation S122 of performing carbonization may be performed for 2 to 10 minutes.

The operation S123 of performing nitridation is an operation of performing nitridation on an upper surface of carbon. Here, NH₃ gas may be supplied at a flow rate of 4,000 sccm or less within 5 minutes, and preferably, at a flow rate of 2,000 sccm or more and 3,000 sccm or less for 3 seconds or more and 3 minutes or less.

In this case, as illustrated in FIG. 2, the temperature may be maintained at 1,100° C., and as illustrated in FIG. 3, NH₃ gas may be introduced at a flow rate of 4,000 sccm. The operation S123 of performing nitridation may be performed for 6 seconds.

When the upper surface of the carbon is not nitrided in the operation S123 of performing nitridation, it may be difficult to grow an inorganic material such as aluminum nitride because there are almost no unsaturated bonds or functional groups on the surface of the carbon.

An operation S124 of forming aluminum nitride is an operation of growing aluminum nitride. Here, active gas including NH₃ gas and HCl gas may be supplied at a flow rate of 1,000 sccm or less within 5 minutes, and preferably, for a 1 minute or more and 5 minutes or less, NH₃ gas may be supplied at a flow rate of 10 sccm or more and 100 sccm or less and HCl gas may be supplied at a flow rate of 100 sccm or more and 1,000 sccm or less.

In this case, as illustrated in FIG. 2, the temperature may be maintained at 1,100° C., and as illustrated in FIG. 3, NH₃ gas may be introduced at a flow rate of 40 sccm and HCl gas may be introduced at a flow rate of 200 sccm. The operation S124 of forming aluminum nitride may be performed for 2 to 3 minutes.

Here, a boat containing an aluminum (Al) metal, which is used as a raw material, may be located in the source zone, a temperature of the zone where the boat is positioned may be maintained at 550° C. to 650° C., then the molten Al metal and HCl gas react, and aluminum chloride (AlCl₃) gas may be generated.

The generated AlCl₃ gas may be moved to the growth zone by carrier gas.

Argon (Ar) gas and nitrogen gas may be used as the carrier gas, and specifically, nitrogen gas may be used.

In the growth zone, the AlCl₃ gas and the NH₃ gas may react and the aluminum nitride (AlN) may be grown.

An operation S125 of unloading a substrate is an operation of collecting a substrate after all processes are completed. In this case, as illustrated in FIG. 2, a furnace is slowly cooled to 25° C.

A separable semiconductor substrate is obtained through the above-described method. Referring to FIG. 4B, a buffer layer 20 includes a first sub-buffer layer 20A, a second sub-buffer layer 20B, and a third sub-buffer layer 20C. Here, the buffer layer 20 is defined as AlN with carbon buffer on sapphire (AWC).

Here, the first sub-buffer layer 20A may be a carbon-containing layer.

Further, the second sub-buffer layer 20B may be a nitrided carbon layer.

Further, the third sub-buffer layer 20C may be an aluminum nitride-containing layer.

Here, when a thickness of the first sub-buffer layer 20A increases, an average light transmittance may decrease.

Further, the carbon-containing layer of the first sub-buffer layer 20A may have a three-dimensional structure.

Further, a surface of the first sub-buffer layer 20A may be significantly smooth.

The obtained semiconductor substrate may be guided to be separated at an interface between the substrate and the first sub-buffer layer 20A during a cooling process.

Here, due to a difference in thermal expansion coefficient between the substrate and the first sub-buffer layer 20A, tensile stress may be applied to a surface of the substrate and compressive stress may be applied to the surface of the first sub-buffer layer 20A based on the interface.

The crystallinity of the buffer layer 20 may be inherited through the third sub-buffer layer 20C.

Here, a surface of the third sub-buffer layer 20C may be significantly smooth.

The buffer layer 20 may be removed using a chemical mechanical polishing (CMP) method.

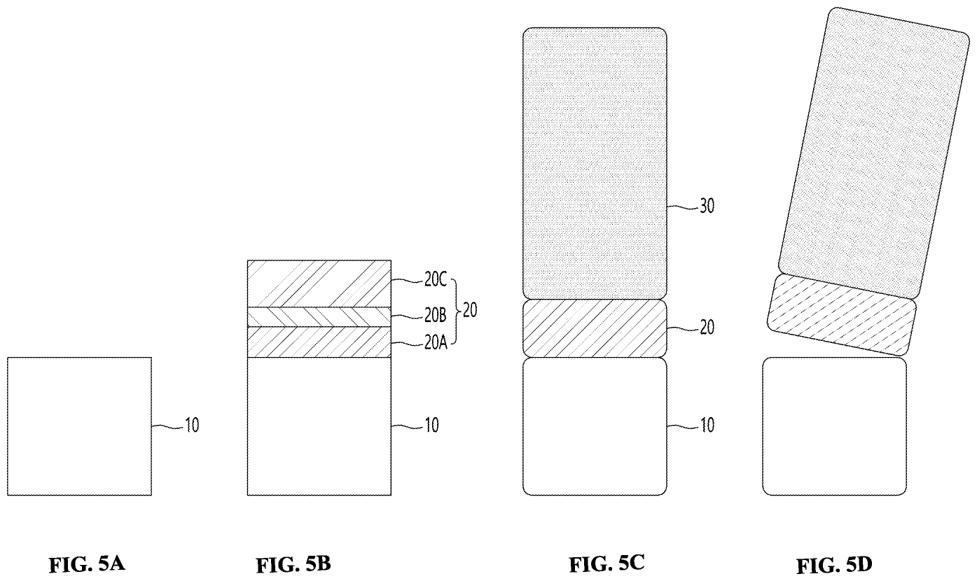

Meanwhile, a compound semiconductor substrate with high-quality crystallinity may be obtained by utilizing the separable semiconductor substrate according to the embodiment of the present invention. Detailed descriptions thereof will be given with reference to FIGS. 5A to 5D together.

FIGS. 5A to 5D are sets of cross-sectional views for describing a method of manufacturing a separable semiconductor substrate according to another embodiment of the present invention and a method of manufacturing a compound semiconductor substrate using the same.

Referring to FIGS. 5A and 5B, a buffer layer 20 is formed on a substrate 10. A process of forming the buffer layer 20 is the same as described with reference to FIGS. 1 to 4B, and the description thereof will not be repeated.

Referring to FIG. 5C, an operation of forming a compound semiconductor layer on the buffer layer 20 and an operation of guiding the compound semiconductor layer to be separated may be further included.

Here, a compound semiconductor may include a nitride or oxide semiconductor. The compound semiconductor may include gallium nitride (GaN), but the present invention is not limited thereto. For example, the compound semiconductor may include an aluminum nitride (AlN), aluminum gallium nitride (AlGaN), gallium oxide (Ga₂O₃), aluminum gallium oxide (AlGa) 203, etc.

In some embodiments, a device layer may be formed on the compound semiconductor.

Meanwhile, a gallium nitride layer 30 may be grown using an HVPE device, and preferably, a vertical HVPE device may be used. The gallium nitride layer 30 may be grown to a thickness of 700 μm or more.

Referring to FIG. 5D, separation may be guided at an interface between the substrate 10 and a first sub-buffer layer 20A after a furnace is slowly cooled.

As described above, since the separable semiconductor substrate according to the embodiment of the present invention includes a gallium nitride layer or an aluminum gallium nitride layer, the compound semiconductor layer formed on the gallium nitride layer or aluminum gallium nitride layer maintains the crystallinity of the gallium nitride layer or aluminum gallium nitride layer disposed thereunder, and thus the crystallinity of the compound semiconductor layer can be improved.

In particular, since the buffer layer 20 has a structure in which the first sub-buffer layer 20A, a second sub-buffer layer 20B, and a third sub-buffer layer 20C are stacked, delamination may be guided due to a difference in thermal expansion coefficient between the first sub-buffer layer 20A and the second sub-buffer layer 20B when a furnace is slowly cooled, and the first sub-buffer layer 20A may be easily self-separated due to Van der Waals bonding of the first sub-buffer layer 20A.

Further, since the method of manufacturing a separable semiconductor substrate according to the embodiment of the present invention is performed in an in-situ method, the process can be performed economically and easily.

Further, since the separable semiconductor substrate according to the embodiment of the present invention has a smooth surface, the quality thereof can be improved.

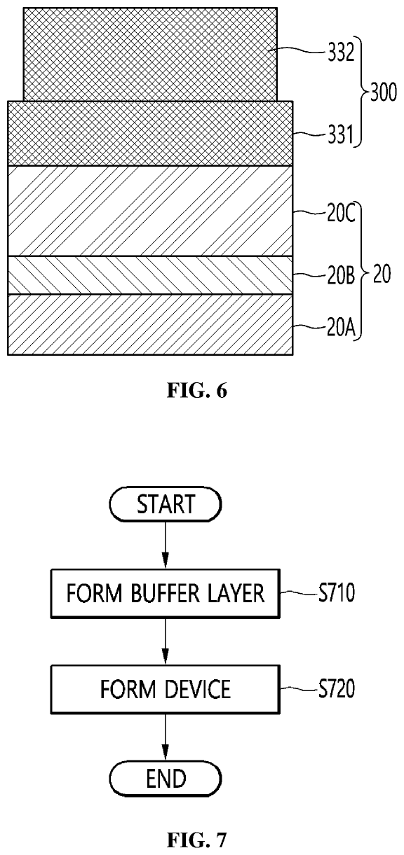

FIG. 6 is a cross-sectional view for describing a thin film device according to an embodiment of the present invention.

As described above, the separable semiconductor substrate according to the embodiment of the present invention may be used as a template or substrate for manufacturing a thin film device, and in particular, may be a suitable substrate for forming a thin film device for a device with flexibility. Hereinafter, a thin film device manufactured using the separable semiconductor substrate of the present invention will be described with reference to FIG. 6.

Referring to FIG. 6, a thin film device 300 according to the embodiment of the present invention includes a semiconductor layer 331 and a device layer 332. In some embodiments, a mother substrate 10 may be further included.

A buffer layer 20 is an intermediate layer that allows a compound semiconductor to be grown with excellent crystallinity and allows the semiconductor layer 331 to be easily separated from the mother substrate 10 later.

As described above, the buffer layer 20 includes a first sub-buffer layer 20A, a second sub-buffer layer 20B, and a third sub-buffer layer 20C, and since each component has been described with reference to FIGS. 1 to 5D, the description thereof will not be repeated. In some embodiments, the buffer layer 20 may be formed on the mother substrate 10. The mother substrate 10 may be used to form the first sub-buffer layer 20A on the mother substrate 10. The mother substrate 10 may be made of sapphire, silicon, silicon carbide, etc.

The device layer 332 is a layer including a device that is a core component of the thin film device 300, and a function of the thin film device 300 may be implemented by the device formed on the device layer 332.

The device layer 332 may be stacked on the buffer layer 20.

The device layer 332 may include a device, and the device may include, for example, at least one of a diode, a light-emitting diode (LED), a transistor, an amplifier, an integrated circuit, an inductor, and a capacitor.

In some embodiments the device layer 332 may be formed on the semiconductor layer 331.

As described above, the semiconductor layer 331 may include a nitride semiconductor or an oxide semiconductor.

The semiconductor layer 331 may be formed to have an appropriate thickness so that electrical characteristics of the device of the device layer 332 can be maintained. For example, the semiconductor layer 331 may be formed to have a thickness of 400 nm to 10 μm. When the thickness of the semiconductor layer 331 is less than 400 nm, the semiconductor layer 331 may be broken or cracked and thus damaged, and such damage may cause degradation of the performance of the thin film device 300 later. When the thickness of the semiconductor layer 331 exceeds 10 μm, there is a problem in that the electrical characteristics are degraded and heat management is difficult.

When the thickness of the semiconductor layer 331 ranges from 400 nm to 10 μm, damage may occur in the device layer 332 during a process of separating the mother substrate 10. In this case, a stress layer that covers the device layer 332 may be further disposed.

The stress layer is a layer that protects the thin film device 300 when the thin film device 300 is separated, and is disposed on the device layer 332 of the thin film device 300. The stress layer may be made of a material with internal tensile strain to relieve stress during mechanical substrate separation. For example, the stress layer may be made of nickel (Ni), copper (Cu), chromium (Cr), gold (Au), titanium (Ti), palladium (Pd), tin (Sn), etc. More preferably, the stress layer may include nickel.

In some embodiments, a support layer may be further disposed on the stress layer.

The support layer is a layer that serves to facilitate the separation of the thin film device 300.

The support layer together with the stress layer may support the thin film device 300 when the thin film device 300 is separated. Further, the support layer is formed to be easily removed through thermal processing after the thin film device 300 is separated.

For example, thermal release tape may be used as the support layer. The thermal release tape may be adhered in contact with the stress layer and the thermal release tape together with the stress layer may guide mechanical separation while minimizing damage to the thin film device 300. After the thin film device 300 is separated, the stress layer and the support layer may be further removed by performing thermal processing on the stress layer and the support layer.

FIG. 7 is a flowchart of a method of manufacturing a thin film device according to an embodiment of the present invention.

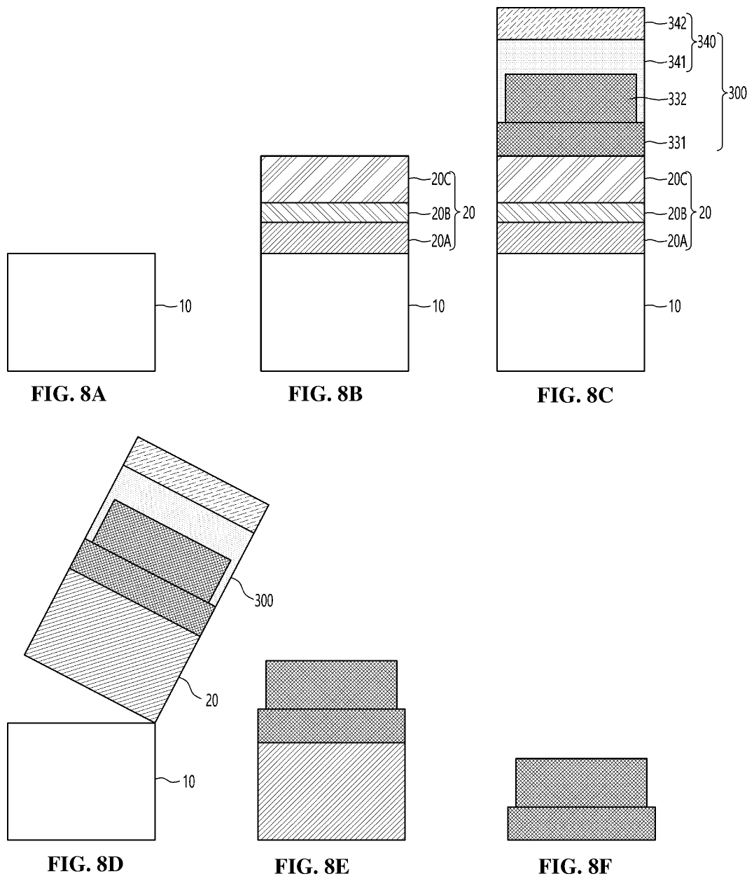

FIGS. 8A to 8F are sets of cross-sectional views for describing the method of manufacturing a thin film device of FIG. 7.

Referring to FIG. 7, in the method of manufacturing a thin film device of the present invention, a buffer layer is formed on a mother substrate (S710).

Referring to FIGS. 8A and 8B, a buffer layer 20 may be manufactured through an operation of performing carbonization for forming the carbon, an operation of performing nitridation on an upper surface of the carbon, and an operation of forming aluminum nitride on the nitrided upper surface of the carbon.

Since the method of forming the buffer layer 20 has been described with reference to FIG. 5A to 5D, the same description will be omitted.

Referring to FIG. 8C, a semiconductor layer 331 may be manufactured through an operation of forming a compound semiconductor layer on the buffer layer 20.

Since the method of forming the semiconductor layer 331 has been described with reference to FIGS. 5A to 5D, the same description will be omitted.

Referring to FIG. 7 again, thereafter, in the method of manufacturing a thin film device, a device layer is formed (S720).

Referring to FIG. 8C, a device layer 332 may be formed in any one of various known methods. Preferably, the device layer 332 may be formed in a method such as a chemical vapor deposition (CVD) method, an HVPE method, an MBE method, a sputtering method, a PECVD method, an ALD method, etc.

In some embodiments, the device layer 332 may include a plurality of micro devices, and the micro devices may be manufactured through a patterning process.

Thereafter, in the method of manufacturing a thin film device, a separation assistant portion 340 may be further formed on the device layer 332.

The separation assistant portion 340 may include a stress layer 341 and a support layer 342.

The stress layer 341 may be formed in any one of various known manufacturing methods, such as plasma sputtering, electroplating, etc. Preferably, the stress layer 341 may be manufactured through electroplating.

When the stress layer 341 is formed through electroplating, the stress layer 341 may be manufactured through a first cleaning operation, a plating operation, a second cleaning operation, and a drying operation. Specifically, in the cleaning operations, distilled water may be used to clean a sample including the buffer layer 20 and the device layer 332. Thereafter, in the plating operation, electroplating may be performed by immersing the sample in an electrolytic plating aqueous solution, connecting a jig, and adjusting a current and voltage using a power supply. In this case, the electroplating may be performed at a temperature range of 50 to 60° C., a distance between the sample and an electrode may be adjusted to 15 to 25 cm, and the electroplating may be performed at a current density of 60 to 80 mA/cm². Thereafter, in the second cleaning operation and the drying operation, a sample including the stress layer 341 may be cleaned with distilled water and dried using nitrogen gas.

In some embodiments, thereafter, the method of manufacturing the thin film device 300 of the present invention may further include an operation of separating a mother substrate 10 from the buffer layer 20 disposed thereunder.

Referring to FIG. 8D, the separation of the mother substrate 10 may be performed through a self-separation or mechanical separation method.

For example, when the semiconductor layer 331 and the device layer 332 are sufficiently thick, the mother substrate 10 may be self-separable. For example, by cooling the thin film device 300 to an appropriate temperature so that stress is applied to the buffer layer 20, self-separation of an interface between the buffer layer 20 and the mother substrate 10 may be guided. In this case, the separation assistant portion 340 for self-separation may be omitted.

Further, when the semiconductor layer 331 and the device layer 332 are thin, the mother substrate 10 may be mechanically separable.

When the mother substrate 10 is mechanically separated, the stress layer 341 may be formed on the device layer 332, the support layer 342 may be bonded onto the stress layer 341, and the thin film device 300 may be separated from the mother substrate 10 by pulling the support layer 342.

As described above, the method of manufacturing the thin film device 300 of the present invention includes a device formation operation and a device separation operation.

That is, a device is formed on the thin film device 300 through the device formation operation, and the mother substrate 10 is separated from the thin film device 300 through the device separation operation.

When the thick mother substrate 10 is separated, the device may be provided in a supported state on the thin buffer layer 20, and accordingly, it is possible to manufacture a thin film device 300.

Further, the method of manufacturing the thin film device 300 according to the embodiment of the present invention may include an operation of forming the separation assistant portion 340 on the device layer 332 and an operation of performing mechanical separation.

In this case, since the stress layer 341 and the support layer 342 that are formed on the device layer 332 are configured to cover the thin device layer 332, damage to the thin film device 300 may be minimized during the operation of performing the mechanical separation. In particular, since a substrate is easily separated by the buffer layer 20, the thickness of the thin film device 300 may be further reduced. Accordingly, it is possible to implement a flexible device such as a nano LED or the like.

Referring to FIG. 8E, the separation assistant portion 340 formed on the device layer 332 may be further removed. The removal of the separation assistant portion 340 may be performed by any one of various methods such as mechanical and chemical methods and the like.

Referring to FIG. 8F, thereafter, the buffer layer 20 may be further removed from the semiconductor layer 331. For example, the removal of the buffer layer 20 may be performed by a polishing method such as a CMP method or the like.

FIG. 9 is a cross-sectional view for describing a composite device according to an embodiment of the present invention.

Referring to FIG. 9, the composite device includes a first electronic device 500 and a second electronic device 400.

The composite device of the present invention has a structure in which two electronic device substrates are stacked.

The first electronic device 500 and the second electronic device 400 may be formed as the same devices or different devices.

The first electronic device 500 and the second electronic device 400 may be stacked in a structure in which one surface of a device layer 332 of the first electronic device 500 is in contact with one surface of a device layer 422 of the second electronic device 400.

For example, as illustrated in FIG. 9, the first electronic device 500 and the second electronic device 400 may be stacked in a method in which the device layer 332 of the first electronic device 500 is disposed at the top and the device layer 422 of the second electronic device 400 is disposed at the bottom so as to be in contact with the device layer 332 of the first electronic device 500. In this case, a substrate layer 410, the device layer 422, and a device substrate layer 421 of the second electronic device 400 may be stacked from the bottom, and the device layer 332, a semiconductor layer 331, and the buffer layer 20 of the first electronic device 500 may be sequentially stacked.

Devices of the device layer 332 of the first electronic device 500 and devices of the device layer 422 of the second electronic device 400 may be in direct contact with each other. However, the present invention is not limited thereto, and the first electronic device 500 and the second electronic device 400 may be stacked with an intermediate insulating layer interposed therebetween. In this case, a connection wire for interconnecting the first electronic device 500 and the second electronic device 400 may be provided on the intermediate insulating layer.

The interconnected first electronic device 500 and second electronic device 400 may be connected and operate as one device. For example, the interconnected first electronic device 500 and second electronic device 400 may operate as a device in which two LED devices are stacked and operate as one pixel.

In some embodiments, the first electronic device 500 and the second electronic device 400 may be formed as different types of devices and operate as separate devices. For example, when the first electronic device 500 and the second electronic device 400 are formed as a display device, the first electronic device 500 may include a thin film transistor (TFT) device for driving a display device, and the second electronic device 400 may include a light-emitting device that constitutes a pixel of a display. In this case, the first electronic device 500 and the second electronic device 400 may be stacked on each other so that a display device may be implemented.

The first electronic device 500 may include a buffer layer 20 and a first device layer 332. The buffer layer 20 of the first electronic device 500 may include a first sub-buffer layer 20A, a second sub-buffer layer 20B, and a third sub-buffer layer 20C.

Since the buffer layer 20 has the same characteristics as those of the buffer layer 20 described with reference to FIGS. 4A and 4B of the present invention, the description of each component will not be repeated.

Since the first device layer 332 has the same characteristics as those of the device layer 332 described with reference to FIG. 6, the description of each component will not be repeated.

The second electronic device 400 may include a mother substrate 10 and a second device layer 422. The mother substrate 10 may include a substrate used in various known device stacking methods. As an example, at least one of silicon, SiC, GaN, GaAs, Al₂O₃, and ZnO may be used.

The second device layer 422 may include at least one of a diode, an LED, a transistor, an amplifier, an integrated circuit, an inductor, and a capacitor.

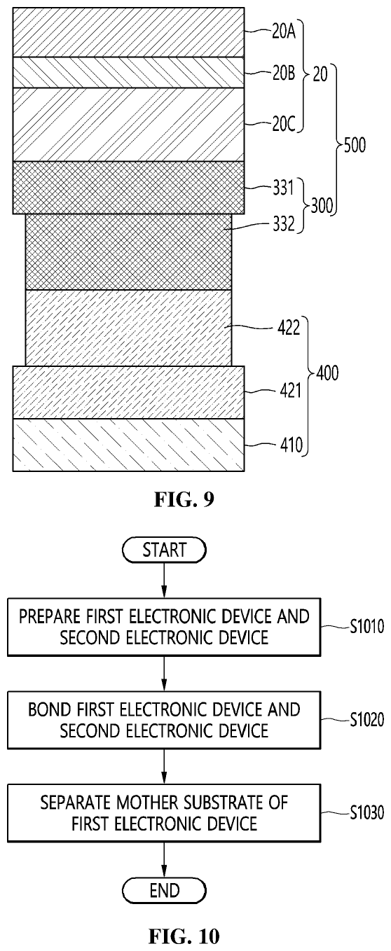

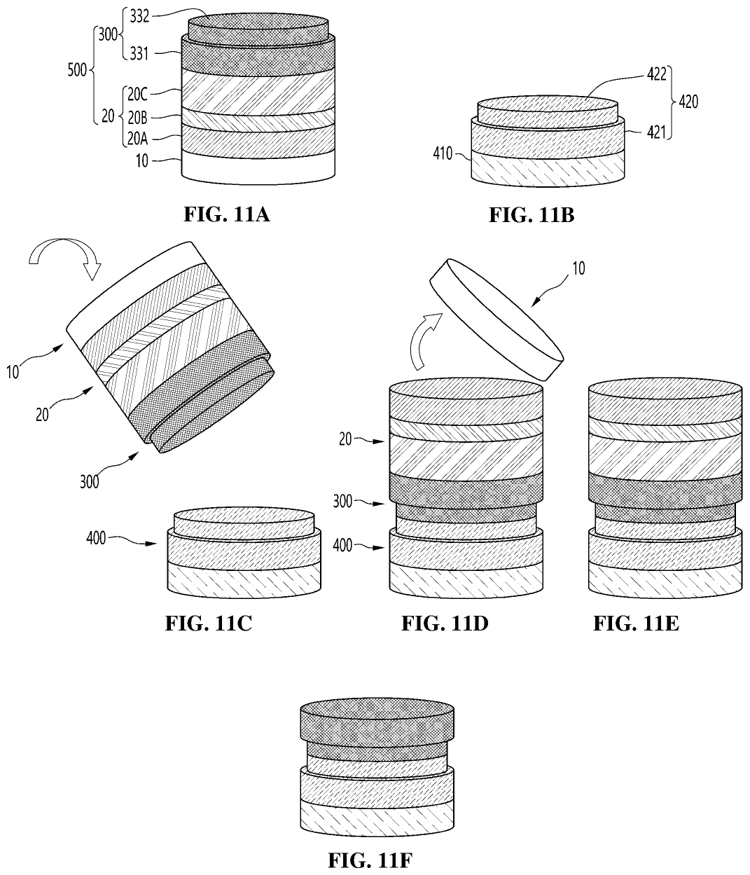

FIG. 10 is a flowchart of a method of manufacturing a composite device according to an embodiment of the present invention.

FIGS. 11A to 11F are schematic diagrams for describing the method of manufacturing a composite device of FIG. 10.

Referring to FIG. 10, in the method of manufacturing a composite device of the present invention, a first electronic device and a second electronic device are prepared (S1010).

Referring to FIG. 11A, preparation of a first electronic device 500 may be an operation of preparing the first electronic device 500 including a buffer layer 20 and a first device layer 332, and the operation of preparing the first electronic device 500 may be the same as that in the method of manufacturing the thin film device 300 with reference to FIGS. 8A to 8F. Accordingly, the description thereof will not be repeated.

Referring to FIG. 11B, preparation of a second electronic device 400 may be an operation of preparing the second electronic device 400 including a substrate layer 410, a second device layer 422, and a device substrate layer 421, and the second electronic device 400 may be prepared by manufacturing the second electronic device 400 by forming the device substrate layer 421 and the second device layer 422 on the substrate layer 410.

Referring to FIG. 10 again, in the method of manufacturing a composite device of the present invention, the first electronic device and the second electronic device are bonded to each other (S1020).

Referring to FIG. 11C, an operation of bonding the first electronic device 500 and the second electronic device 400 may be performed by allowing the first device layer 332 of the first electronic device 500 to be in contact with an upper portion of the second device layer 422 of the second electronic device 400 and performing thermal processing at 300 to 500° C. Preferably, a composite device may be manufactured by performing thermal processing at 400° C. or higher to guide bonding of the first device layer 332 and the second device layer 422. However, the present invention is not limited thereto, and as a method of bonding different types of devices to each other, the first electronic device 500 and the second electronic device 400 may be bonded to each other through various bonding methods.

Referring to FIG. 10 again, in the method of manufacturing a composite device of the present invention, the mother substrate of the first electronic device is separated (S1030). Referring to FIG. 11D, for example, by performing thermal processing on the mother substrate 10 of the first electronic device 500 and then cooling the mother substrate 10 of the first electronic device 500 to 25° C., a process of guiding the mother substrate 10 to be self-separated may be performed. In this case, due to a difference in thermal expansion coefficient between the mother substrate 10 and the first sub-buffer layer 20A, tensile stress may be applied to a surface of the mother substrate 10 and compressive stress may be applied to a surface of the first sub-buffer layer 20A based on the interface.

The mother substrate 10 of the first electronic device 500 may be self-separated due to the tensile stress of the mother substrate 10 and the compressive stress of the first sub-buffer layer 20A.

In some embodiments, the mother substrate 10 may be mechanically separated. For example, the mother substrate 10 may be mechanically separated by bonding a support layer onto the exposed surface of the mother substrate 10 and applying mechanical stress thereto. In some embodiments, referring to FIG. 11E, the buffer layer 20 may be further removed from the composite device from which the mother substrate 10 is removed. In this case, the buffer layer 20 may be removed by mechanical separation, and a separation assistant unit for removing the buffer layer 20 may be disposed on the buffer layer 20.

When the buffer layer 20 is removed, a composite device in which the device layer 332 and the semiconductor layer 331 of the first electronic device 500 are bonded onto the second electronic device 400 may be provided, as illustrated in FIG. 11F, and a thin composite device may be easily provided.

Hereinafter, the effect of the separable semiconductor substrate according to the embodiment of the present invention facilitating self-separation of the compound semiconductor layer will be described with reference to the following experimental examples.

### Manufacturing Examples 1 to 5—Manufacture of Substrate Including Buffer Layer

Substrates according to manufacturing examples were manufactured in the following manner.

First, a 4-inch sapphire substrate was loaded into a horizontal HVPE device. Specifically, as illustrated in Table 1 below, substrates of Manufacturing Examples 1 to 5 were manufactured by forming a buffer layer by varying a carbonization time.

TABLE 1

| | | | Aluminum |
|---|---|---|---|
| | | | nitride |
| | Carbonization | Nitridation | formation |
| | (min.) | (min.) | (min.) |
| Manufacturing Example 1 | 0 | 0.1 | 2.3 |
| Manufacturing Example 2 | 2.5 | 0.1 | 2.3 |
| Manufacturing Example 3 | 5.4 | 0.1 | 2.3 |
| Manufacturing Example4 | 10 | 0.1 | 2.3 |
| Manufacturing Example 5 | 15 | 0.1 | 2.3 |

Carbonization was performed by supplying CH₄ gas at a flow rate of 100 sccm for 0, 2.5, 5.4, 10, and 15 minutes in a source zone maintained at a temperature of 1,100° C. Nitridation was performed by supplying NH₃ gas at a flow rate of 4,000 sccm for 0.1 minutes (i.e., 6 seconds). Next, aluminum nitride was grown by supplying NH₃ gas and HCl gas at a flow rate of 400 sccm for 2.3 minutes (i.e., 138 seconds). Thereafter, the growth-completed substrate was obtained by slowly cooling the furnace to room temperature of 25° C.

### (Experimental Example 1—Ultraviolet-Visible (UV-Vis) Analysis)

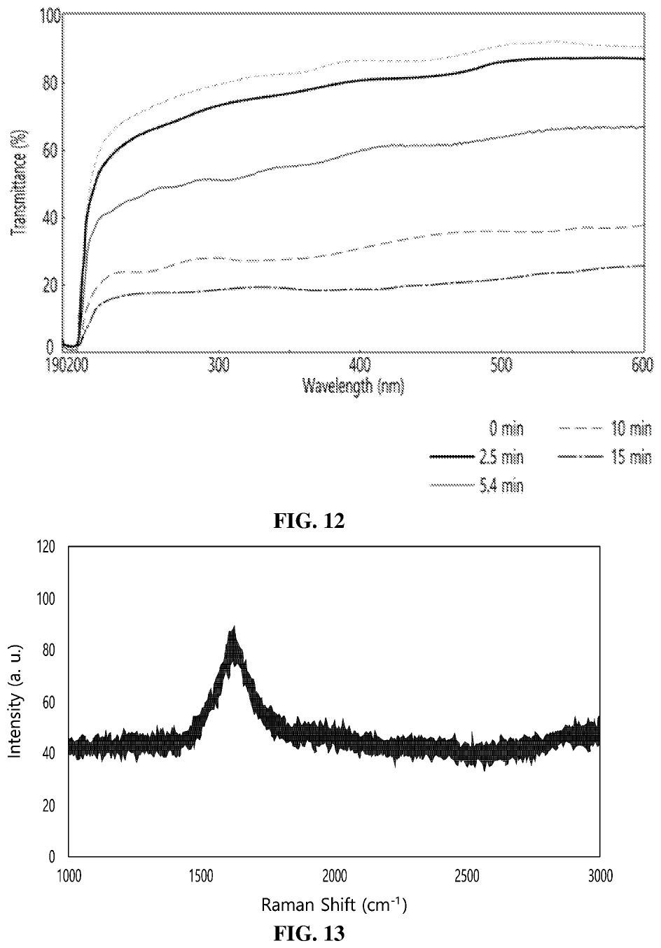

In Manufacturing Examples 1 to 5, transmittances were evaluated using a UV-Vis spectrophotometer. Results of the evaluation are as shown in FIG. 12.

FIG. 12 is a graph of transmittances of semiconductor substrates that are obtained using UV-Vis spectrophotometry according to a thickness of a carbon layer of a separable semiconductor substrate according to an embodiment of the present invention.

Referring to FIG. 12, it can be seen that an average light transmittance of the separable semiconductor substrate is reduced by 20 to 80% of an average light transmittance of a mother substrate with respect to light having a wavelength of 400 nm.

Specifically, when supply times of CH₄ gas were 0, 2.5, 5.4, 10, and 15 minutes, the average light transmittances for light with a wavelength of 400 nm were 85, 73, 60, 30, and 18%, respectively, and an average light transmittance of Manufacturing Example 3 was reduced by 30% of an average light transmittance of Manufacturing Example 1.

In consideration that the light transmittance was reduced, it can be predicted that there is a carbon layer on an upper surface of a buffer layer, and it was confirmed that a thickness of the carbon layer may be controlled according to the supply time of CH₄ gas.

### Experimental Example 2—Raman Analysis

Raman analysis was performed on Manufacturing Example 3 at room temperature using a Raman spectrophotometer equipped with a 532 nm laser.

FIG. 13 is a Raman spectrum for a separable semiconductor substrate according to an embodiment of the present invention.

Referring to FIG. 13, a carbon layer was analyzed as the form of an amorphous layer that has an sp3 structure with a peak around a wavelength of 1,620 cm⁻¹ in a D′ band in a Raman spectrum.

Therefore, it was confirmed that the structure of the carbon layer is a three-dimensional structure with Van der Waals bonds between atomic layers.

### Experimental Example 3—Analysis of Surface Shape and Surface Roughness

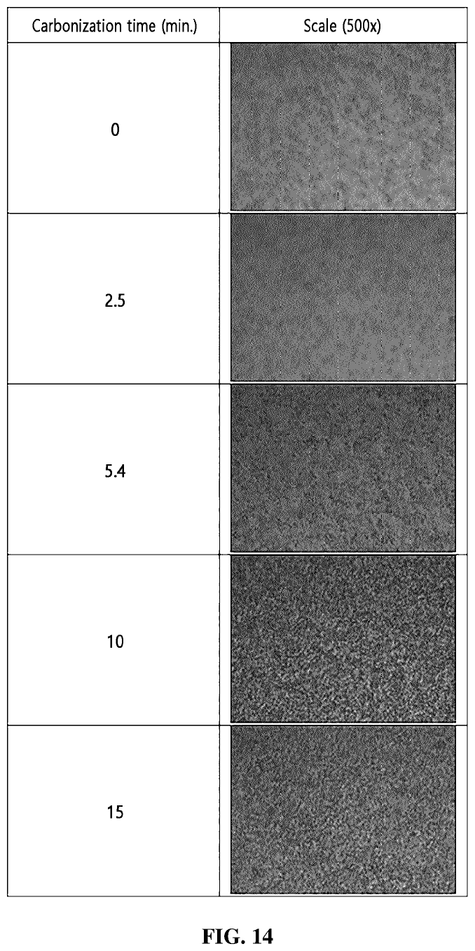

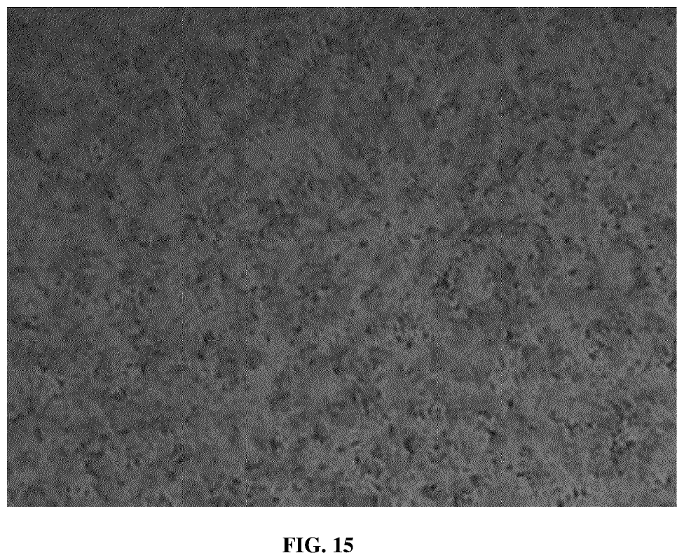

Using Manufacturing Examples 1 to 5, surface shapes and surface roughnesses of a carbon layer and an aluminum nitride layer were analyzed using a Dektak 150 surface inspector. Results of the analysis are as shown in Table 2 below, and the surface shapes are as shown in FIGS. 14 and 15.

FIG. 14 is a photograph of a surface shape according to a thickness of a carbon-containing layer of a separable semiconductor substrate according to an embodiment of the present invention.

FIG. 15 is a photograph of a surface shape of an aluminum nitride layer of a separable semiconductor substrate according to an embodiment of the present invention.

TABLE 2

| | Process | | | | | |
|---|---|---|---|---|---|---|
| | | | | | | Aluminum |
| | | | | | | nitride |
| | Carbonization | | | | | formation |
| | Manufacturing | Manufacturing | Manufacturing | Manufacturing | Manufacturing | Manufacturing |
| Specimen | Example 1 | Example 2 | Example 3 | Example 4 | Example 5 | Example 3 |
| Time (min.) | 0 | 2.5 | 5.4 | 10 | 15 | 2.3 |
| Ra (nm) | 16.4 | 14.9 | 22.1 | 27.2 | 22.4 | 18.0 |
| Rt (nm) | 137.1 | 163.1 | 307.1 | 295.0 | 253.2 | 166.8 |

Referring to Table 2 and FIG. 14, it can be seen that a surface roughness Ra of the carbon layer is 27 nm or less and a surface roughness Rt is 310 nm or less.

Referring to Table 2 and FIG. 15, it can be seen that a surface roughness Ra of the aluminum nitride layer is 20 nm or less and a surface roughness Rt is 170 nm or less.

As illustrated in FIG. Table 2, when a carbonization time was 5.4 minutes, the surface roughness Ra of the carbon layer was 22.1 nm and the surface roughness Rt was 307.1 nm, and when an aluminum nitride formation time was 2.3 minutes, the surface roughness Ra of the aluminum nitride layer was 18 nm and the surface roughness Rt was 166.8 nm.

Therefore, a buffer layer including the manufactured carbon layer and aluminum nitride layer is considered to be a high-quality separable semiconductor substrate that facilitates crystal growth and has a nanoscale surface.

Meanwhile, in order to confirm the ease of separation of the separable substrate of the present invention, a gallium nitride substrate was manufactured and it was confirmed whether the gallium nitride substrate was self-separable.

### Manufacturing Example 6—Manufacture of Gallium Nitride Substrate

A gallium nitride substrate was manufactured by growing gallium nitride on the substrate of Manufacturing Example 3.

Specifically, after the substrate of Manufacturing Example 3 was inserted into a vertical HVPE device, a metal gallium was used as a source, HCl gas was introduced to generate gallium chloride (GaCl) gas, and gallium nitride was grown by introducing NH₃ gas together in a growth zone maintained at a temperature of 1,000° C. Thereafter, slowly cooling the furnace was performed to room temperature of 25° C. to obtain the gallium nitride substrate of Manufacturing Example 6.

### Experimental Example 4—Confirmation of Self-Separation of Aluminum Nitride

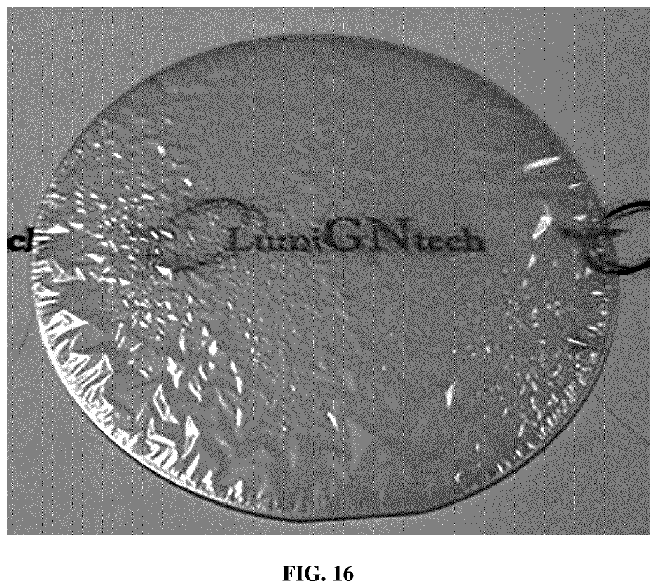

The possibility of self-separation was confirmed by removing the sapphire substrate from the substrate of Manufacturing Example 3, which was furnace-cooled to room temperature of 25° C. Results of the confirmation are as shown in FIG. 16.

FIG. 16 is a photograph of an aluminum nitride layer that is separated from a sapphire substrate after the aluminum nitride layer is grown on a separable semiconductor substrate according to an embodiment of the present invention.

Referring to FIG. 16, it was confirmed that the aluminum nitride layer had self-separated from the sapphire substrate and was swollen.

### Experimental Example 5—Confirmation of Self-Separation of Gallium Nitride

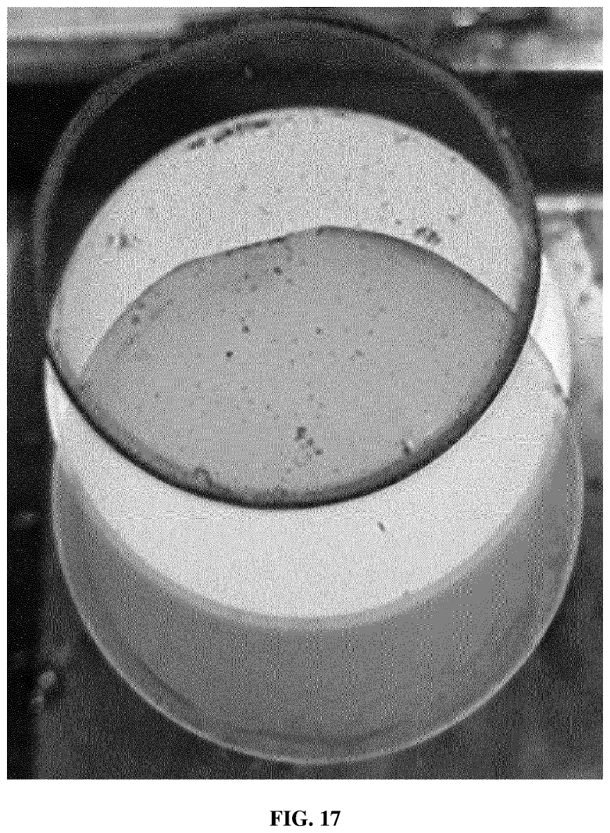

The possibility of self-separation was confirmed by removing the sapphire substrate from the substrate of Manufacturing Example 6, in which the furnace was slowly cooled to room temperature of 25° C. Results of the confirmation are as shown in FIG. 17.

FIG. 17 is a photograph of a gallium nitride layer that is separated from a sapphire substrate after the gallium nitride layer is grown on a separable semiconductor substrate according to an embodiment of the present invention.

Referring to FIG. 17, it can be seen that the gallium nitride layer was easily separated from the sapphire substrate, and it was confirmed that no cracks or destruction occurred in the gallium nitride substrate.

According to any one of the solutions of the present invention described above, an embodiment of the present invention can provide a method of manufacturing a semiconductor substrate on which an area of a compound semiconductor layer is enlarged. Further, according to any one of the solutions of the present invention, an embodiment of the present invention can provide a method of manufacturing a semiconductor substrate from which a compound semiconductor layer is easily separated.

Further, according to any one of the solutions of the present invention, in an embodiment of the present invention, a thin compound semiconductor layer can be easily separated.

Further, according to any one of the solutions of the present invention, in an embodiment of the present invention, a process of manufacturing a separable semiconductor substrate can be facilitated because the separable semiconductor substrate is manufactured in an in-situ method.

Further, according to any one of the solutions of the present invention, in an embodiment of the present invention, a thickness of a carbon layer of a separable semiconductor substrate can be easily adjusted.

Further, according to any one of the solutions of the present invention, in an embodiment of the present invention, a separable semiconductor substrate can be used to manufacture a thin film device.

According to any one of the solutions of the present invention described above, in an embodiment of the present invention, a thin film device can include a buffer layer including carbon and aluminum nitride, an electronic device layer disposed on the buffer layer, and a stress layer that covers the electronic device layer, and thus the thin film device and a mother substrate can be easily separated.

Further, according to any one of the solutions of the present invention, an embodiment of the present invention can further include a support layer that guides a thin film device to be separated, and thus the thin film device can be separated without damage. In particular, a substrate can be easily separated by a buffer layer, and thus a thickness of the thin film device can be made smaller.

According to any one of the solutions of the present invention described above, in an embodiment of the present invention, a composite device can include a first electronic device that includes a buffer layer including carbon and aluminum nitride and a first device layer formed on the buffer layer, and a second electronic device disposed below the first electronic device and including a second device layer in contact with a surface facing the first device layer and formed as a single structure with the first device layer, and thus it is possible to implement a device that can operate as a single structure formed by connecting various thin composite devices.

Further, according to any one of the solutions of the present invention, an embodiment of the present invention can further include a separable substrate disposed on a first electronic device, and thus a substrate can be separated while a first electronic device and a second electronic device are bonded, and a complex composite device can be manufactured rapidly and easily.

The effects obtainable in the present invention are not limited to the above-described effects and other effects that are not described may be clearly understood by those skilled in the art from the above detailed descriptions.

The scope of the present invention is defined not by the detailed description but by the appended claims, and encompasses all modifications or alterations derived from meanings, the scope and equivalents of the appended claims.

The above description is only exemplary, and it will be understood by those skilled in the art that the present invention may be performed in other concrete forms without changing the technological scope and essential features. Therefore, the above-described embodiments should be considered as only examples in all aspects and not for purposes of limitation. For example, each component described as a single type may be realized in a distributed manner, and similarly, components that are described as being distributed may be realized in a coupled manner.

What is claimed is:

1. A method of manufacturing a separable semiconductor substrate, comprising:
providing a substrate; and
forming a buffer layer including carbon and aluminum nitride.

2. The method of claim 1, further comprising:
forming a compound semiconductor layer on the buffer layer; and
guiding the compound semiconductor layer to be self-separated.

3. The method of claim 2, wherein the compound semiconductor layer includes gallium nitride (GaN), aluminum nitride (AlN), and aluminum gallium nitride (AlGaN).

4. The method of claim 1, wherein the substrate is a sapphire substrate with a size of 2 inches or more.

5. The method of claim 1, wherein the forming of the buffer layer includes:
performing carbonization for forming the carbon;
performing nitridation on an upper surface of the carbon; and
forming the aluminum nitride on the nitrided upper surface of the carbon.

6. A separable semiconductor substrate comprising:
a mother substrate; and
a buffer layer disposed on the mother substrate and including carbon and aluminum nitride.

7. The separable semiconductor substrate of claim 6, wherein the separable semiconductor substrate has a size of 2 inches or more.

8. The separable semiconductor substrate of claim 6, wherein an average light transmittance of the separable semiconductor substrate has an average light transmittance reduced by 20 to 80% compared to an average light transmittance of the mother substrate with respect to light having a wavelength of 400 nm.

9. The separable semiconductor substrate of claim 6, wherein the buffer layer includes a carbon layer, a nitride layer, and an aluminum nitride layer.

10. The separable semiconductor substrate of claim 9, wherein the carbon layer has a three-dimensional structure.

11. The separable semiconductor substrate of claim 9, wherein the carbon layer is an amorphous layer that has an sp3 structure with a peak around a wavelength of 1,620 cm⁻¹ in a D band in a Raman spectrum.

12. The separable semiconductor substrate of claim 9, wherein the carbon layer has a surface roughness Ra of 27 nm or less and a surface roughness Rt of 310 nm or less.

13. The separable semiconductor substrate of claim 9, wherein the aluminum nitride layer has a surface roughness Ra of 20 nm or less and a surface roughness Rt of 170 nm or less.

14. The separable semiconductor substrate of claim 6, further comprising: a first electronic device disposed on the buffer layer.

15. The separable semiconductor substrate of claim 14,
Wherein the mother substrate is separable from the buffer layer.

16. The separable semiconductor substrate of claim 15, further comprising:
a stress layer that covers the first electronic device; and
a support layer disposed on the stress layer.

17. The separable semiconductor substrate of claim 6, further comprising:
a second electronic device including a second device layer in contact with a surface of a first device layer of the first electronic device and formed as a single structure with the first device layer.
